(19) United States
(12) Patent Application Publication
(10) Pub. No.: US 2016/0109512 A1
(43) Pub. Date: Apr. 21, 2016

(54) SEMICONDUCTOR PACKAGE TEST BLADE AND SEMICONDUCTOR PACKAGE TEST APPARATUS INCLUDING THE SAME

(71) Applicant: Samsung Electronics Co., Ltd., Suwon-si (KR)

(72) Inventors: Suk-lae Kim, Chungcheongnam-do (KR); Dong-joo Roh, Chungcheongnam-do (KR)

(21) Appl. No.: 14/687,205

(22) Filed: Apr. 15, 2015

(30) Foreign Application Priority Data
Oct. 16, 2014 (KR) 10-2014-0140163

(51) Int. Cl. G01R 31/28; G01R 1/073

(52) U.S. Cl. CPC G01R 31/2893; G01R 31/2887; G01R 1/07307

(57) ABSTRACT

A semiconductor package test blade and a semiconductor package test apparatus may prevent damage to a semiconductor package and occurrence of failures in the semiconductor package during a pass/fail test on the semiconductor package. The semiconductor package test blade includes a blade body formed at a lower end portion of a pusher for testing a semiconductor package, the blade body having a first surface contacting the semiconductor package and a groove dented upward from the first surface, a vacuum suction picker configured to penetrate a central portion of the blade body and suck and pick up the semiconductor package in vacuum, and a flexible silicone layer filling the groove. A bottom surface of the flexible silicone layer may be positioned at substantially the same level as the first surface of the blade body.

### CROSS-REFERENCE TO RELATED APPLICATION

This application claims under 35 U.S.C. §119 priority to and the benefit of Korean Patent Application No. 10-2014-0140163, filed on Oct. 16, 2014, in the Korean Intellectual Property Office, the disclosure of which is incorporated herein in its entirety by reference.

### BACKGROUND

The inventive concepts relate to a semiconductor package test blade and a semiconductor package test apparatus, which are connected to a semiconductor package test handler apparatus, and more particularly, to a semiconductor package test blade and a semiconductor package test apparatus, which may prevent damage to a semiconductor package during a pass/fail test on semiconductor packages.

The development of a semiconductor package has progressed to reduce power consumption and increase operating speed. A method of performing a pass/fail test on the semiconductor package includes fixing a socket board on which a socket is mounted, by using a socket board fixing jig, and determining whether the semiconductor package is operational or defective by an electrical contact of the socket mounted on the socket board with the semiconductor package. The above-described pass/fail test on the semiconductor package may be performed by using a test handler including a pusher. Specifically, the semiconductor package may be pressed against the socket by using the pusher.

### SUMMARY

The inventive concepts provides a semiconductor package test blade and a semiconductor package test apparatus, which may prevent damage to semiconductor packages during a pass/fail test on semiconductor packages.

According to an aspect of the inventive concepts, a semiconductor package test blade may include: a blade body formed at a lower end portion of a pusher for testing a semiconductor package, the blade body having a first surface contacting the semiconductor package and a groove dented upward from the first surface to provide a second surface at a higher level than the first surface and opposite to the first surface, a vacuum suction picker configured to penetrate a central portion of the blade body and suck and pick up the semiconductor package by using a vacuum, and a flexible silicone layer filling the groove and being in contact with a second surface of the blade body. The second surface of the blade body may serve as a bottom surface of the groove. A bottom surface of the flexible silicone layer is at substantially the same level as the first surface of the blade body.

In some embodiments, the flexible silicone layer may comprise flexible silicone having a hardness of 1 to 10.

In some embodiments, the flexible silicone layer may comprise flexible silicone, or flexible silicone rubber.

In some embodiments, the flexible silicone layer may have a smaller planar area than a planar area of the blade body.

In some embodiments, the bottom side of the vacuum suction picker and the bottom surface of the flexible silicone layer may be in contact with a top surface of the semiconductor package.

In some embodiments, a sum of a planar area the flexible silicone layer and a planar area of the vacuum suction picker may be greater than a planar area of a semiconductor chip included in the semiconductor package to cover the semiconductor chip.

In some embodiments, the first surface of the blade body may be disposed in an outward direction relative to the second surface of the blade body.

In some embodiments, a bottom side of the vacuum suction picker may have a circular cross-sectional shape. A bottom surface of the flexible silicone layer may have a concentric sectional shape with the vacuum suction picker.

In some embodiments, a bottom side of the vacuum suction picker may have a circular cross-sectional shape. A bottom surface of the flexible silicone layer may have a squared sectional shape to surround the vacuum suction picker.

According to another aspect of the inventive concepts, a semiconductor package test apparatus may include: a plurality of test blades disposed in a row apart from one another, each test blade including a vacuum suction picker configured to suck and pick up a semiconductor package, a pusher block connected to the plurality of test blades and including a vacuum path communicate with each vacuum suction picker, and flexible silicone layers each on a first surface of each of the plurality of test blades, which are in contact with the semiconductor package.

In some embodiments, the semiconductor package test apparatus may further include protrusions at outer portions of the first surfaces of the plurality of test blades.

In some embodiments, bottom surfaces of the protrusions may be at substantially the same level as a bottom surface of the flexible silicone layer.

In some embodiments, the pusher block may be connected to a test handler and be in contact with second surfaces of the plurality of test blades opposite to the first surfaces thereof.

In some embodiments, the test blades may include at least one array including eight (8) test blades arranged in a row.

In some embodiments, the flexible silicone layer comprises flexible silicone having a hardness of 1 to 10.

According to another aspect of the inventive concepts, a semiconductor package test blade may include: a vacuum suction unit configured to suck and pick up a semiconductor package, a body unit configured to surround of the vacuum suction unit, wherein a groove is formed to a predetermined depth in a surface of the body unit, which is in contact with the semiconductor package, and a buffer unit configured to fill the groove and formed of a flexible material.

In some embodiments, the flexible silicone layer may be formed of flexible silicone having a hardness of 1 to 10.

In some embodiments, the vacuum suction unit may be disposed to the center of the body unit, and the silicone layer may be symmetrically formed with respect to the vacuum suction unit.

In some embodiments, the vacuum suction unit may be positioned in the center of the body unit, and the flexible silicone layer may be formed as a donut type around the vacuum suction unit.

In some embodiments, a lowermost surface of the body unit may be at substantially a same level as a lowermost surface of the flexible silicone layer.

### BRIEF DESCRIPTION OF THE DRAWINGS

Example embodiments of the inventive concepts will be more clearly understood from the following detailed description taken in conjunction with the accompanying drawings in which:

FIG. 1 is a flowchart illustrating a method of performing a pass/fail test on semiconductor packages according to an example embodiment of the inventive concepts;

FIG. 2 is a schematic conceptual diagram of a semiconductor package test handler according to an example embodiment of the inventive concepts;

FIG. 3 is an enlarged perspective view of some elements of a semiconductor package test apparatus according to an example embodiment of the inventive concepts;

FIG. 4 is a cross-sectional view of a semiconductor package test apparatus according to an example embodiment of the inventive concepts;

FIG. 5 is a cross-sectional view of a semiconductor test blade according to an example embodiment of the inventive concepts;

FIG. 6 is a bottom view of a semiconductor test blade according to an example embodiment of the inventive concepts;

FIG. 7 is an enlarged perspective view of some elements of a semiconductor package test apparatus according to an example embodiment of the inventive concepts;

FIG. 8 is a cross-sectional view of a semiconductor test apparatus according to an example embodiment of the inventive concepts; and

FIGS. 9 and 10 are bottom views of a semiconductor test apparatus according to an example embodiment of the inventive concepts.

### DETAILED DESCRIPTION OF EMBODIMENTS

The inventive concepts will be described more fully hereinafter with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Meanwhile, spatially relative terms, such as “between” and “directly between” or “adjacent to” and “directly adjacent to” and the like, which are used herein for ease of description to describe one element or feature's relationship to another element(s) or feature(s) as illustrated in the figures, should be interpreted similarly.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concept.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “top end,” “bottom end,” “top surface,” “bottom surface,” “upper,” “lower” and the like, may be used herein for ease of description to, describe one element or feature's relationship to another element(s) or feature(s) as illustrated in the figures. It will be understood that the spatially relative terms are intended to encompass different orientations of the device in use or operation in addition to the orientation depicted in the figures.

Unless otherwise defined, all terms (including technical and scientific terms) used herein have the same meaning as commonly understood by one of ordinary skill in the art to which this inventive concept belongs.

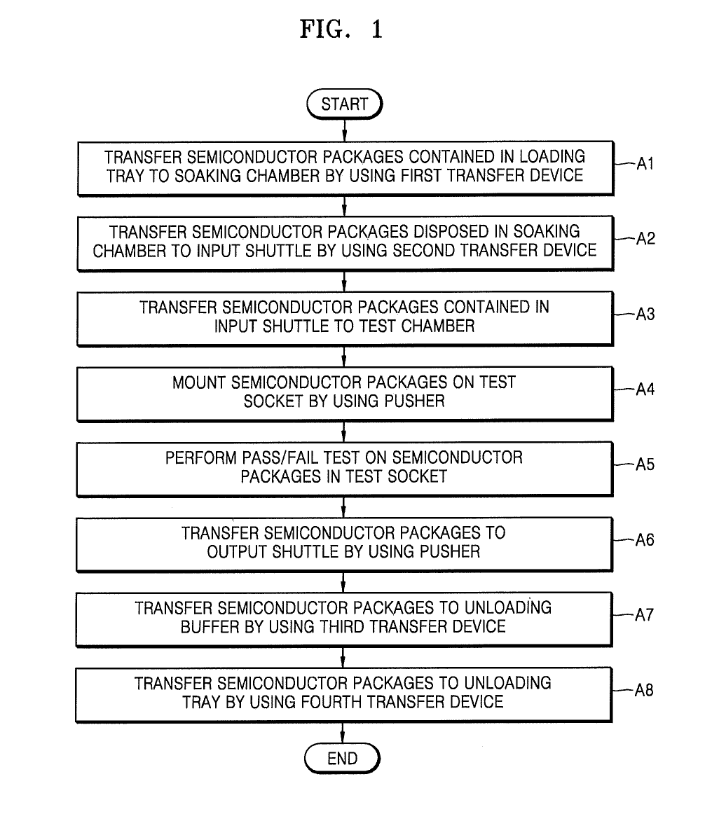

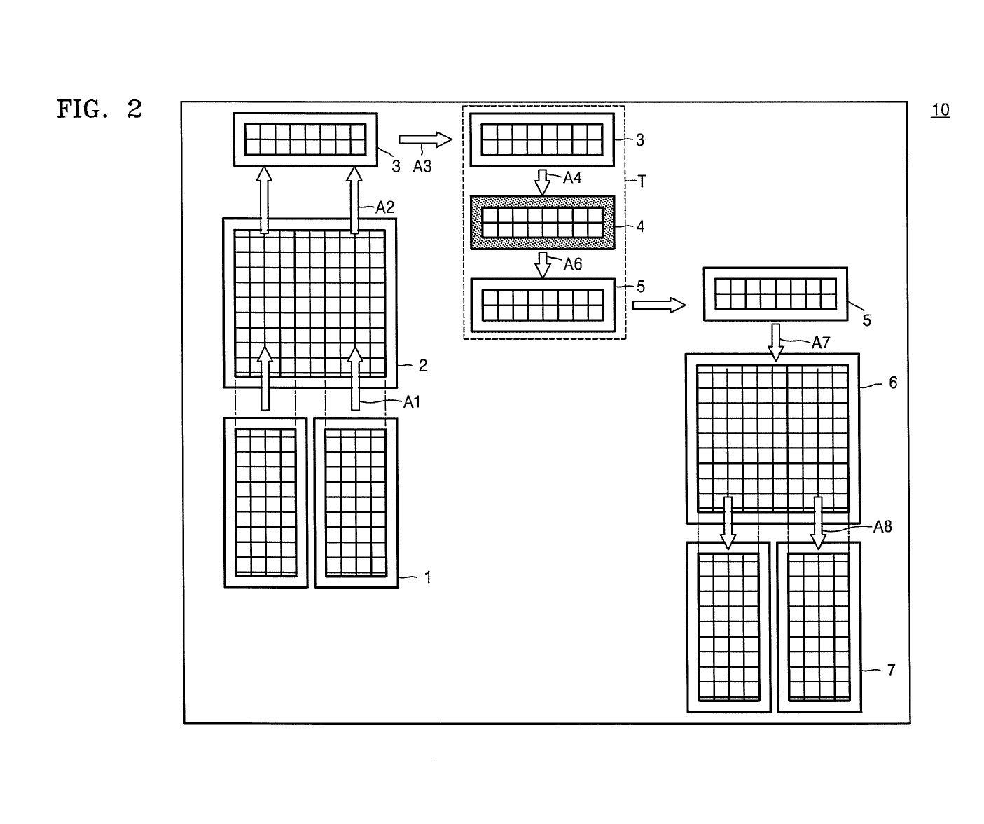

FIG. 1 is a flowchart illustrating a method of performing a pass/fail test on semiconductor packages using a semiconductor package test handler 10 according to an example embodiment of the inventive concept, and FIG. 2 is a schematic conceptual diagram of some elements of the semiconductor package test handler 10 according to an example embodiment of the inventive concepts. In FIG. 2, elements included in the semiconductor package test handler 10 may be schematically illustrated for brevity, and some elements of the semiconductor package test handler 10 may be omitted or exaggerated to be unlike actual shapes thereof.

Referring to FIGS. 1 and 2, the semiconductor package test handler 10 may be a kind of automatic testing robot, which may load semiconductor packages to electrically connect the semiconductor packages with a test apparatus, perform an automatic test by electrically connecting the loaded semiconductor packages with the test apparatus, sorting operational semiconductor packages from defective semiconductor packages based on the test result, and unloading the sorted semiconductor packages. A method of performing a pass/fail test on semiconductor packages using the semiconductor package test handler 10 may include transferring semiconductor packages contained in a loading tray 1 to a soaking chamber 2 by using a first transfer device (A1), transferring the semiconductor packages disposed in the soaking chamber 2 to an input shuttle 3 by using a second transfer device (A2), transferring the semiconductor packages contained in the input shuttle 3 to a test chamber T (A3), mounting the semiconductor packages on test sockets 4 by using a pusher (A4), performing a pass/fail test on the semiconductor packages in the test sockets 4 (A5), transferring the semiconductor packages to an output shuttle 5 by using the pusher (A6), transferring the semiconductor packages to an unloading buffer 6 by using a third transfer device (A7), and transferring the semiconductor packages to an unloading tray 7 by using a fourth transfer device (A8). In some embodiments, the first to fourth transfer devices may be respectively different transfer devices. Each of the first to fourth transfer devices may be pick-and-place equipment configured to pick up semiconductor packages and put the semiconductor packages down. Here, the illustration of the first to fourth transfer devices is omitted for brevity.

The semiconductor package test handler 10 may include the loading tray 1, the soaking chamber 2, the input shuttle 3, the test chamber T, the test sockets 4, the output shuttle 5, the unloading buffer 6, and the unloading tray 7.

A plurality of semiconductor packages to be tested may be contained in the loading tray 1. The loading tray 1 may be a transporting/handling tool in which the semiconductor packages are contained in a matrix shape. The loading tray 1 may be categorized as either a customer tray used to transfer semiconductor packages from user, or a test tray used only in a handler to connect the semiconductor packages with a tester. The loading tray 1 may be connected to the first transfer device and transferred to the soaking chamber 2 (A1).

In the soaking chamber 2, a process of aging the test tray transferred from the loading tray 1 may be performed under predetermined temperature conditions for a predetermined amount of time. The soaking chamber 2 may be used to test electrical performance of semiconductor packages at a high temperature or at a low temperature. The soaking chamber 2 may include a hot plate configured to heat the semiconductor packages at a high temperature. The semiconductor packages, which have passed the soaking chamber 2, may be connected to a second transfer device and transferred to the input shuttle 3 (A2).

The semiconductor packages contained in the input shuttle 3 may be transferred to a test chamber T in which a pass/fail test is performed (A3). For example, the input shuttle 3 containing semiconductor packages therein may be transferred to a test chamber T. The test chamber T may include test sockets 4. 16 semiconductor packages contained in the input shuttle 3 may be arranged in two arrays, each of which includes 8 semiconductor packages. However, the number of semiconductor packages that may be contained in the input shuttle 3 is not limited to 16, and at least one semiconductor package may be contained in the input shuttle 3. The semiconductor packages contained in the input shuttle 3 may be mounted on the test sockets 4 by using the pusher connected to the semiconductor package test handler 10 (A4). In the test sockets 4, a pass/fail test including an electrical performance test may be performed on the semiconductor packages (A5). In some embodiments, the test sockets 4 may be configured to perform the pass/fail test on a total of 16 semiconductor packages at one time. However, the number of semiconductor packages on which the pass/fail test is performed at one time in the test sockets 4 is not limited to 16. The test sockets 4 may be connected to a test head configured to perform the pass/fail test on the semiconductor packages. The semiconductor packages on which the pass/fail test has been performed in the test sockets 4 may be transferred to the output shuttle 5 and discharged out of the test chamber T (A6). For example, the output shuttle 5 containing semiconductor packages therein may be transferred out of the test chamber T.

The semiconductor packages contained in the output shuttle 5 may be transferred by the third transfer device to the unloading buffer 6 (A7). Similar to the input shuttle 3, 16 semiconductor packages may be contained in the output shuttle 5. However, the number of semiconductor packages that may be contained in the output shuttle 5 is not limited to 16. The unloading buffer 6 may perform a process of aging the semiconductor packages on which the pass/fail test is completely performed, at room temperature for a predetermined amount of time.

The semiconductor packages, which have passed the unloading buffer 6, may be transferred to the unloading tray 7 by the fourth transfer device (A8).

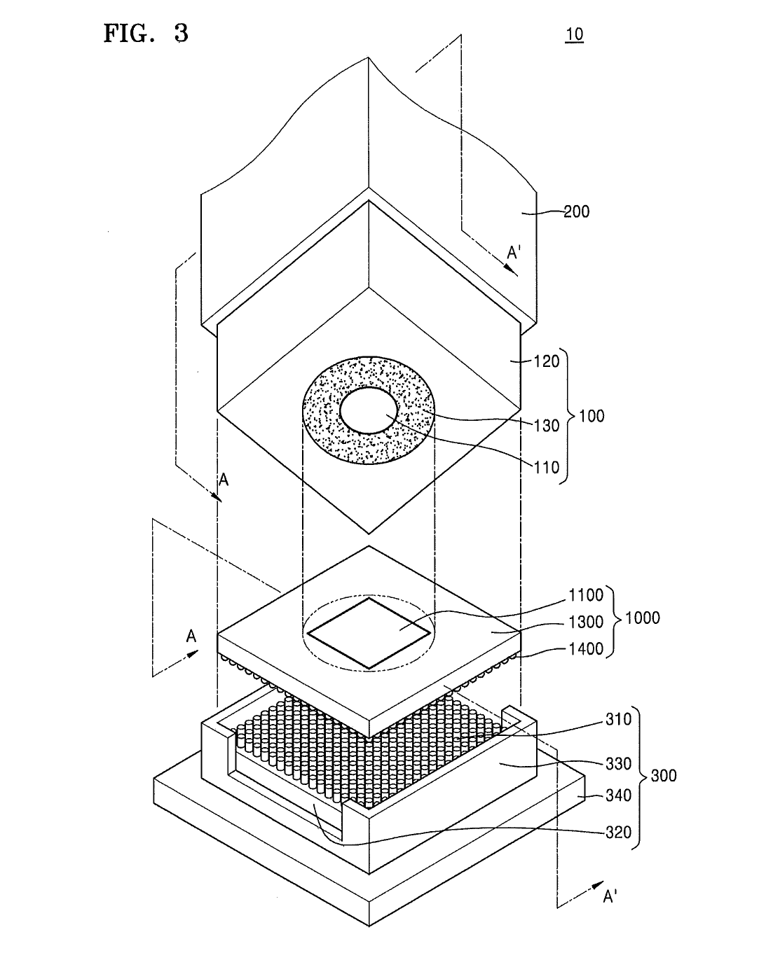

In some embodiments, the above-described operation A4 of mounting the semiconductor packages on the test sockets 4 by using the pusher may include sucking and picking up the semiconductor packages in vacuum by using the pusher connected to the semiconductor package test handler 10, and putting the semiconductor packages down on the test sockets 4. A test blade (refer to 100 in FIG. 3) may be formed at a lower end portion of the pusher.

FIG. 3 is an enlarged perspective view of some elements of a semiconductor package test apparatus 10 according to an example embodiment of the inventive concepts.

Referring to FIG. 3, the semiconductor package test handler 10 may include a test blade 100, a pusher block 200 connected to the semiconductor package test handler 10 and having a bottom end portion at which the test blade 100 is formed, and a socket structure 300. The socket structure 300 may be the same element as each of the test sockets 4 shown in FIG. 2.

The test blade 100 may include a vacuum suction picker 110, a blade body 120 formed to surround the vacuum suction picker 110, a flexible silicone layer 130 formed on a surface of the blade body 120, which may be in contact with a semiconductor package 1000, The test blade 100 may be formed at the bottom end portion of the pusher block 200. In some embodiments, the test blade 100 may comprise a pusher, which may apply pressure to a top surface of the semiconductor package 1000 and mount the semiconductor package 1000 on the socket structure 300.

In some embodiments, the blade body 120 may have, for example, a hexahedral shape. However, the blade body 120 is not limited thereto and may have various shapes including a cylindrical shape or a polygonal shape. A planar area of the test blade 100 (e.g., a planar area of a bottom surface of the test blade 100) may be greater than a planar area of the top surface of the semiconductor package 1000 and substantially equal to a planar area of the socket substrate 320. The bottom surface of the blade body 120 may be formed at a planar level without a step difference. The blade body 120 may be formed of a metal material, such as aluminum (Al), copper (Cu), nickel (Ni), tungsten (W), tin (Sn), silver (Ag), or gold (Au). In an example embodiment of the inventive concept, the blade body 120 may be formed of aluminum.

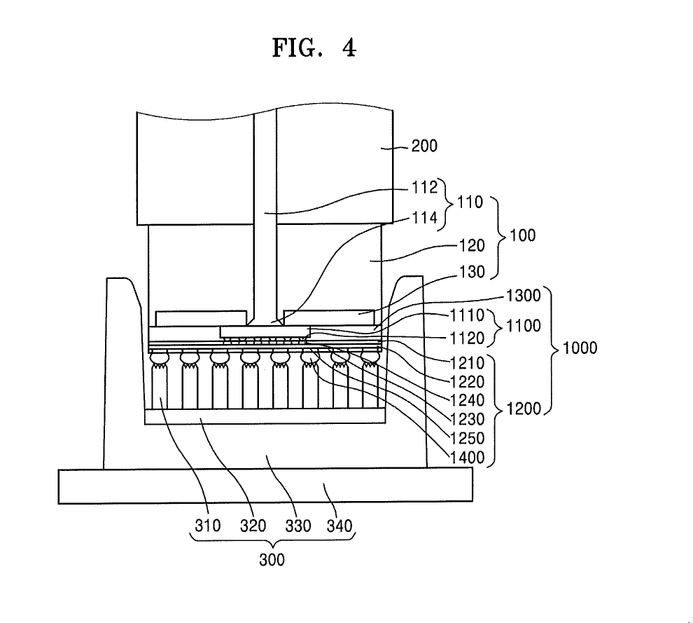

The vacuum suction picker 110 may be formed to penetrate a central portion of the blade body 120. The vacuum suction picker 110 may include the vacuum path (refer to 112 in FIG. 4) and the suction head (refer to 114 in FIG. 4). The vacuum suction picker 110 may be in contact with a top surface of the semiconductor package 1000 and suck and pick up the semiconductor package 1000 in vacuum. The bottom side of the vacuum suction picker 110 may have a circular sectional shape.

The flexible silicone layer 130 may be formed on the bottom surface of the blade body 120. The flexible silicone layer 130 may be formed around the vacuum suction picker 110 to surround the vacuum suction picker 110. The flexible silicone layer 130 may have a concentric sectional shape with the vacuum suction picker 110. For example, the flexible silicone layer 130 may have a donut shape to surround the vacuum suction picker 110.

In some embodiments, a planar area of the flexible silicone layer 130 may be smaller than the planar area of the semiconductor package 1000. A sum of planar areas of the flexible silicone layer 130 and the vacuum suction picker 110 may be greater than a planar area of a semiconductor chip 1100 included in the semiconductor package 1000. The flexible silicone layer 130 may be brought into contact with the top surface of the semiconductor package 1000 and/or the top surface of the semiconductor chip 1100 by the pusher block 200 so that the semiconductor package 1000 may be in contact with the socket structure 300. In some embodiments, the flexible silicone layer 130 may cover the top surface of the semiconductor chip 1100 except for a portion corresponding to the vacuum suction picker 110.

The flexible silicone layer 130 may be formed of a flexible material. For example, the flexible silicone layer 130 may be formed of flexible silicone, flexible silicone rubber. In some embodiments, the flexible silicone layer 130 may be formed of any one of flexible materials including polyurethane, polymer, synthetic resin. In other embodiments, the flexible silicone layer 130 may be formed of flexible silicone having a hardness of 1 to 10.

The pusher block 200 may be connected to a top surface of the test blade 100. The pusher block 200 may be connected to the semiconductor package test handler 10 and move upward and downward by a motor included in the semiconductor package test handler 10. As the pusher block 200 moves upward and downward, the test blade 100 also may move upward and downward. The test blade 100 may be brought into contact with the semiconductor package 1000 so that the semiconductor package 1000 may be mounted on the socket structure 300.

The socket structure 300 may include pogo-pins 310, a socket substrate 320, a socket body unit 330, and a test board 340. The socket body unit 330 may have a shape corresponding to an external shape of the test blade 100. That is, when the test blade 100 is moved downward by the pusher block 200 and brought into contact with the socket structure 300, the socket body unit 330 may surround at least a portion of outer side surfaces of the test blade 100 (refer to FIG. 4). A planar area of the socket substrate 320 may be substantially equal to a planar area of the test blade 100. The pogo-pins 310 may be respectively in contact with and connected to external connection members 1400 of the semiconductor package 1000, and may be connected to the test board 340 through the socket substrate 320.

The semiconductor package 1000 may be mounted on the socket structure 300. The semiconductor package 1000 may be pressed against the socket structure 300 by the test blade 100 connected to the pusher block 200. The semiconductor package 1000 may include a semiconductor chip 1100, a substrate 1200, a molding member 1300, and an external connection member 1400. The semiconductor package 1000 will be described in detail below with reference to FIG. 4.

FIG. 4 is a cross-sectional view taken along a line A-A′ of FIG. 3, which illustrates the semiconductor package test handler 10 shown in FIG. 3.

Referring to FIG. 4, the pusher block 200 may move downward so that the semiconductor package 1000 may be mounted on the socket structure 300. A bottom surface of the test blade 100 formed at a lower end portion of the pusher block 200 may be in contact with the top surface of the semiconductor package 1000, and may apply pressure to the semiconductor package 1000. The socket body unit 330 may have a shape corresponding to the test blade 100. That is, when the test blade 100 moves downward to the socket body unit 330, the socket body unit 330 may be tightly adhered to and surround a side surface portion of the test blade 100.

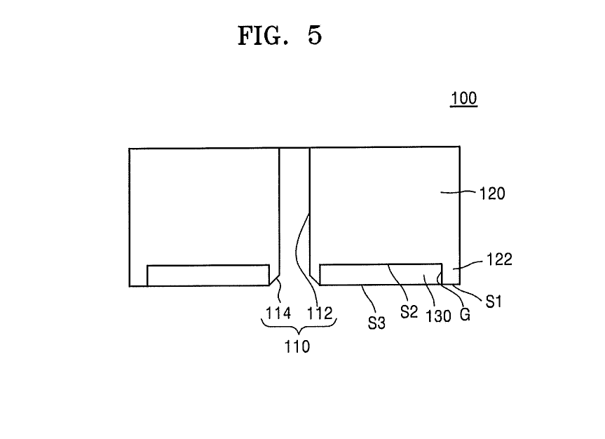

The bottom surface of the blade body 120, and a bottom surface of the flexible silicone layer 130 may be at substantially the same level, which may be in contact with the semiconductor package 1000, may be flattened without causing a step difference, which will be described in detail with reference to FIG. 5.

The semiconductor package 1000 may include a semiconductor chip 1100, a substrate 1200, a molding member 1300, and external connection members 1400. The substrate 1200 may include an upper layer 1210, a body layer 1220, a lower layer 1230, upper pads 1240, and lower pads 1250. The semiconductor chip 1100 may be mounted on the substrate 1200. The semiconductor chip 1100 may include a semiconductor device 1110 and connection terminals 1120. The semiconductor chip 1100 may be a microprocessor (MP). a central processing unit (CPU), a controller, an application specific integrated circuit (ASIC), or an application processor (AP) used for a mobile phone or a smartphone. The semiconductor chip 1100 may be a memory chip such as a DRAM chip, a FLASH memory chip or a MRAM chip. A top surface of the semiconductor chip 1100 may not be covered with the molding member 1300 and may be exposed. In some embodiments, the top surface of the semiconductor chip 1100 may be covered with the molding member 1300. The external connection members 1400 may be electrically and/or physically connected to the lower pads 1250 of the substrate 1200. The lower pads 1250 may be connected to the upper pads 1240 through the body layer 1220. As a result, the external connection members 1400 may be electrically connected to the semiconductor chip 1100.

When the pusher block 200 moves downward and the test blade 100 applies pressure due to the downward movement of the pusher block 200, the semiconductor package 1000 may be in contact with and mounted on the socket structure 300. The external connection members 1400 of the semiconductor package 1000 may be electrically and/or physically connected to the pogo-pins 310 of the socket structure 300. By electrically connecting the pogo-pins 310 with the semiconductor chip 1100, the socket structure 300 may test electrical performance and performance characteristics (e.g., radio-frequency (RF) signals and audio signals) of the semiconductor package 1000 and perform a pass/fail test on the semiconductor package 1000.

During the above-described operation of performing the pass/fail test on the semiconductor package 1000, the pusher block 200 may move downward and the test blade 100 may apply pressure to the top surface of the semiconductor package 1000. Therefore, when the semiconductor package 1000 is mounted on the socket structure 300 in contact with the socket structure 300, the semiconductor package 1000 may be damaged or broken.

For example, when foreign materials flow between the bottom surface of the test blade 100 and the top surface of the semiconductor package 1000, the foreign materials may apply pressure to the semiconductor package 1000 so that the semiconductor package 1000 may become damaged. In particular, as shown in FIG. 4, when the semiconductor chip 1100 is exposed, the semiconductor package 1000 may be damaged and judged as a failure. In the test blade 100 and the semiconductor package test handler 10 including the test blade 100 according to an example embodiment of the inventive concept, the flexible silicone layer 130 formed of a flexible material may be disposed on a bottom surface of the test blade 100, so that even if foreign materials flow between the test blade 100 and the semiconductor package 1000 and a pass/fail test is performed, pressure applied to the semiconductor package 1000 may be reduced. That is, even if the foreign materials flow between the test blade 100 and the semiconductor package 1000, the flexible silicone layer 130 may absorb the foreign materials and prevent damage to the semiconductor package 1000. In an example embodiment of the inventive concept, since the flexible silicone layer 130 is formed of a flexible silicone material having a hardness of 1 to 10, when the inflow of foreign materials occurs, the flexible silicone layer 130 may be deformed to absorb the foreign materials. When the pusher block 200 moves upward, the test blade 100 is unloaded, and the test blade 100 is separated from the semiconductor package 1000 again, the foreign materials absorbed into the flexible silicone layer 130 may be externally discharged again. Accordingly, by performing the pass/fail test on the semiconductor package 1000 using the test blade 100 including the flexible silicone layer 130, damage to and failures in the semiconductor package 1000 may be prevented, thereby reducing fabrication and testing costs. Furthermore, an additional operation for sorting defective semiconductor packages from the semiconductor packages 1000 may be omitted, thereby increasing process efficiency.

FIG. 5 is a cross-sectional view of a test blade 100 according to an example embodiment of the inventive concepts.

Referring to FIG. 5, a vacuum suction picker 110 may be formed to penetrate a central portion of the test blade 100. A groove G, which is dent upward, may be formed in a bottom portion of the blade body 120. A bottom surface of the groove may be at a level of a second surface S2. That is, a first surface S1 and the second surface S2 may be formed in the blade body 120. For example, a bottom surface of the blade body may include the first surface S1 and the second surface S2. The second surface S2 may be positioned opposite to the first surface S1 at a higher level than a level of the first surface S1. The first surface S1 may be disposed in an outward direction relative to the second surface S2 in a bottom portion of the blade body 120. The blade body 120 may include a protrusion 122 disposed outward relative to the groove G.

A flexible silicone layer 130 may fill the groove G and contact the second surface S2. The flexible silicone layer 130 may be symmetrically formed with respect to the vacuum suction picker 110. A level S3 of a lowermost surface (or a bottom surface) of the flexible silicone layer 130 may be substantially the same as the level of the first surface S1. In other words, a bottom surface of the test blade 100 (i.e., the first surface S1 of the blade body 120, the lowermost surface S3 of the flexible silicone layer 130 may be at substantially the same level. Accordingly, the bottom surface of the test blade 100, which is in contact with a top surface of a semiconductor package 1000, may be flattened without causing a step difference.

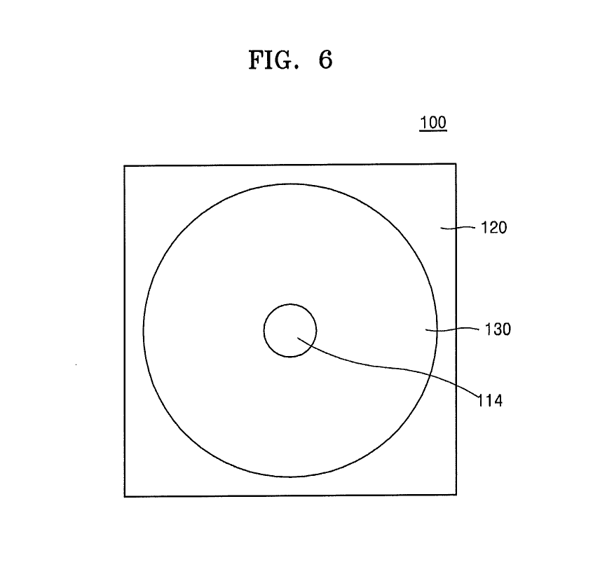

FIG. 6 is a bottom view of a test blade 100 according to an example embodiment of the inventive concepts.

Referring to FIG. 6, a bottom surface of the test blade 100 may include a bottom surface of a blade body 120, and a bottom surface of a flexible silicone layer 130. The bottom side suction head 114 may have a circular sectional shape. The bottom surface of the flexible silicone layer 130 may have a concentric sectional shape with the suction head 114. In some embodiments, the flexible silicone layer 130 may be formed as a donut-type configuration around the suction head 114 to surround the suction head 114.

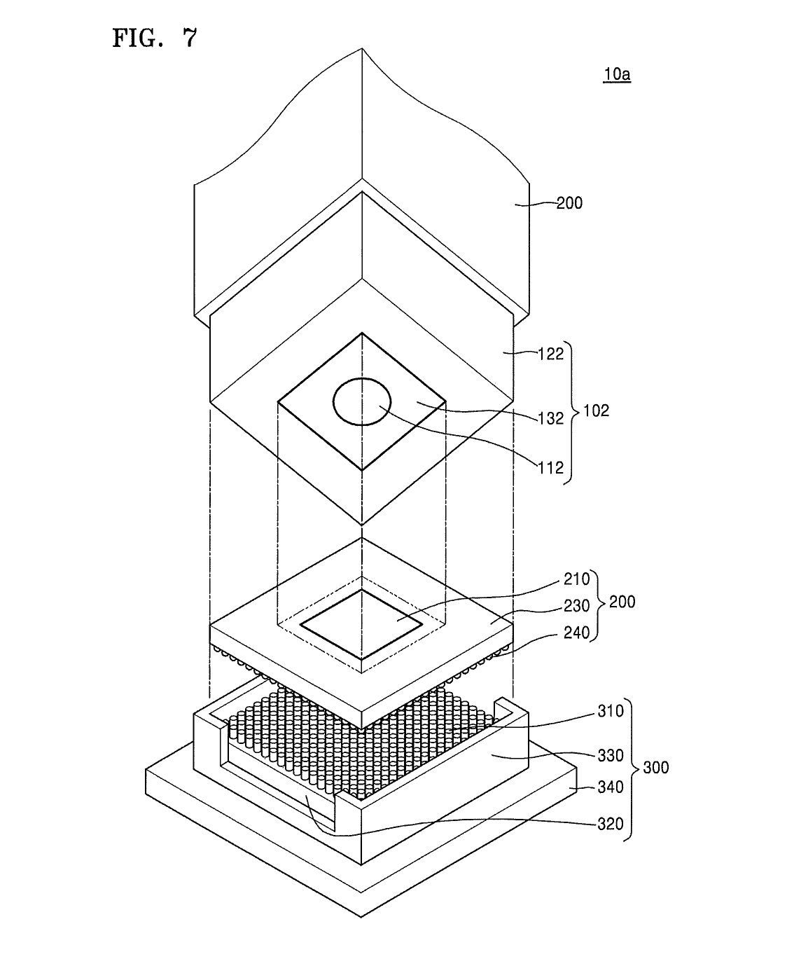

FIG. 7 is an enlarged perspective view of some elements of a semiconductor package test handler 10a according to an example embodiment of the inventive concepts.

Referring to FIG. 7, the semiconductor package test handler 10a may include a test blade 102, a pusher block 200, and a socket structure 300. Since the pusher block 200 and the socket structure 300 are the same as shown in FIG. 3 except for the test blade 102, repeated descriptions thereof are omitted. The semiconductor package test handler 10a shown in FIG. 7 differs from the semiconductor package test handler 10 shown in FIG. 3 in a shape of the test blade 102. Hereinafter, the shape of the test blade 102 will chiefly be described in detail.

The test blade 102 may include a vacuum suction picker 110, a blade body 122 formed to surround a side surface portion of the vacuum suction picker 112, and a flexible silicone layer 132 formed on a surface of the blade body 122, which is in contact with a semiconductor package 1000. The test blade 102 may be formed at a lower end portion of the pusher block 200. The test blade 102 may be a pusher, which may apply pressure to a top surface of the semiconductor package 1000 and mount the semiconductor package 1000 on the socket structure 300.

The blade body 122 may have a hexahedral shape. A planar area of the test blade 102 may be greater than a planar area of the top surface of semiconductor package 1000, and substantially equal to a planar area of a socket substrate 320. The blade body 122 may be formed of, for example, aluminum (Al). In some embodiments, the blade body 122 may be formed of copper (Cu), nickel (Ni), tungsten (W), tin (Sn), silver (Ag), or gold (Au).

A vacuum suction picker 112 may be formed in a central portion of the blade body 122 to penetrate the blade body 122. Since the vacuum suction picker 112 is formed in the same shape as the vacuum suction picker 110 shown in FIG. 3, repeated descriptions thereof are omitted.

A flexible silicone layer 132 may be formed on a bottom surface of the blade body 122. The flexible silicone layer 132 may be formed around the vacuum suction picker 112 to surround the vacuum suction picker 110. A bottom surface of the flexible silicone layer 132 may have a squared sectional shape to surround the vacuum suction picker 112. The flexible silicone layer 132 may not cover the entire bottom surface of the blade body 122 to expose a portion of the bottom surface of the blade body 122. The exposed portion of the bottom surface of the blade body 122 may be disposed outward relative to the flexible silicone layer 132.

In some embodiments, a planar area of the flexible silicone layer 132 may be smaller than a planar area of the semiconductor package 1000. A sum of planar areas of the flexible silicone layer 132 and the vacuum suction picker 112 may be greater than a planar area of the semiconductor chip 1100. The flexible silicone layer 132 may cover the top surface of the semiconductor chip.

The flexible silicone layer 132 may be formed of a flexible material. For example, the flexible silicone layer 132 may be formed of flexible silicone. Since the flexible silicone layer 132 is formed of the same material as the flexible silicone layer 130 shown in FIG. 3, repeated descriptions thereof are omitted.

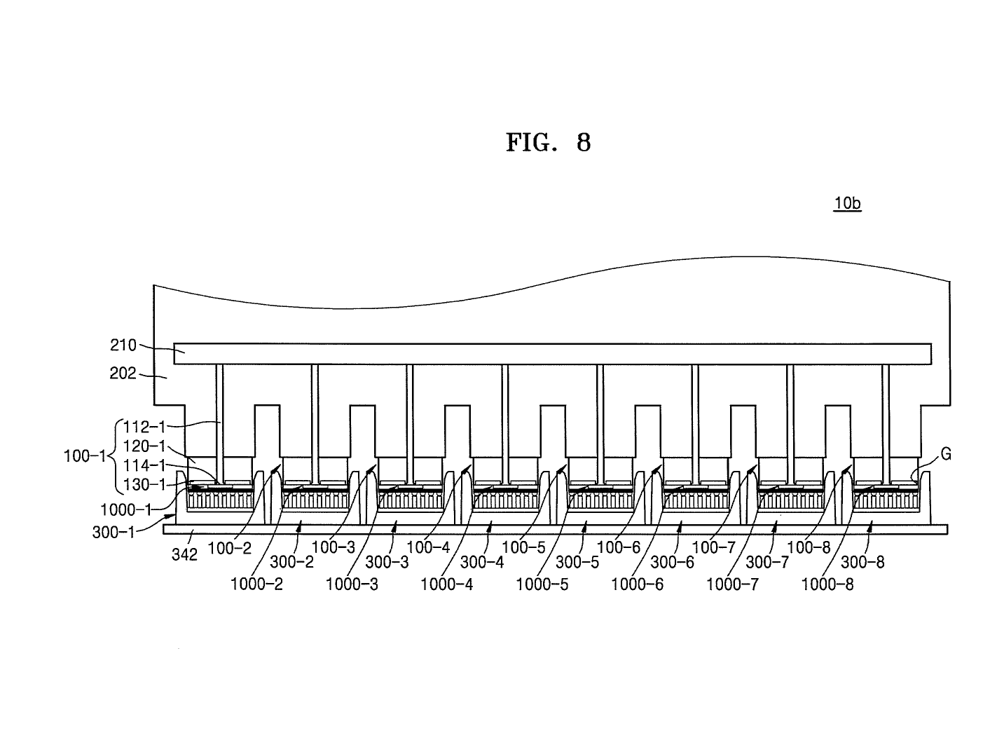

FIG. 8 is a cross-sectional view of some elements of a semiconductor package test handler 10b according to an example embodiment of the inventive concepts.

Referring to FIG. 8, the semiconductor package test handler 10b may include a plurality of test blades 100-1 to 100-8, a pusher block 202, and a plurality of socket structures 300-1 to 300-8. The plurality of test blades 100-1 to 100-8 may be positioned to be spaced a predetermined distance apart from one another. The plurality of socket structures 300-1 to 300-8 may be spaced a predetermined distance apart from one another.

The plurality of test blades 100-1 to 100-8 may include 8 test blades, namely, first to eighth test blades 100-1 to 100-8. However, the number of test blades 100-1 to 100-8 is not limited to 8, and at least one test blade may be provided. The plurality of test blades 100-1 to 100-8 may be disposed in a row and form an array. Each of the plurality of test blades 100-1 to 100-8 may be the same as the test blade 100 shown in FIGS. 3 through 6 and thus, repeated descriptions thereof will be omitted.

A top surface of each of the plurality of test blades 100-1 to 100-8 may be connected to a lower end portion of the pusher block 202. The plurality of test blades 100-1 to 100-8 may be connected to one another by the pusher block 202. The pusher block 202 may be connected to the semiconductor package test handler 10b. The pusher block 202 may apply pressure to the plurality of test blades 100-1 to 100-8 so that a plurality of semiconductor packages 1000-1 to 1000-8 may be mounted on a plurality of socket structures 300-1 to 300-8, respectively.

A vacuum path 210 may be formed in the pusher block 202 and communicate with a plurality of vacuum suction pickers 120-1 to 120-8. Vacuum generated by the semiconductor package test handler 10b) may be transmitted to the plurality of vacuum suction pickers 120-1 to 120-8, which may communicate with the vacuum path 210. Thus, the plurality of vacuum suction pickers 120-1 to 120-8 may suck and pick up the plurality of semiconductor package 1000-1 to 1000-8, respectively.

The plurality of socket structures 300-1 to 300-8 may include 8 socket structures, namely, first to eighth socket structures 300-1 to 300-8, which may correspond to the plurality of test blades 100-1 to 100-8. The first socket structure 300-1 may correspond to the first test blade 100-1, the second socket structure 300-2 may correspond to the second test blade 100-2, and an n-th socket structure may correspond to an n-th test blade. The plurality of socket structures 300-1 to 300-8 may be connected to a test board 342.

The semiconductor package test handler 10b may include the plurality of test blades 100-1 to 100-8 and the pusher block 202 connected to the plurality of test blades 100-1 to 100-8 so that the plurality of semiconductor packages 1000-1 to 1000-8 may be simultaneously mounted on the plurality of socket structures 300-1 to 300-8. Similar to the test blade 100 shown in FIGS. 3 through 6, the plurality of test blades 100-1 to 100-8 may include flexible silicone layers 130-1 to 130-8, respectively. Thus, when the plurality of test blades 100-1 to 100-8 apply pressure to the plurality of semiconductor packages 1000-1 to 1000-8, damage to or defects in the semiconductor packages 1000-1 to 1000-8 due to the presence of foreign materials may be prevented.

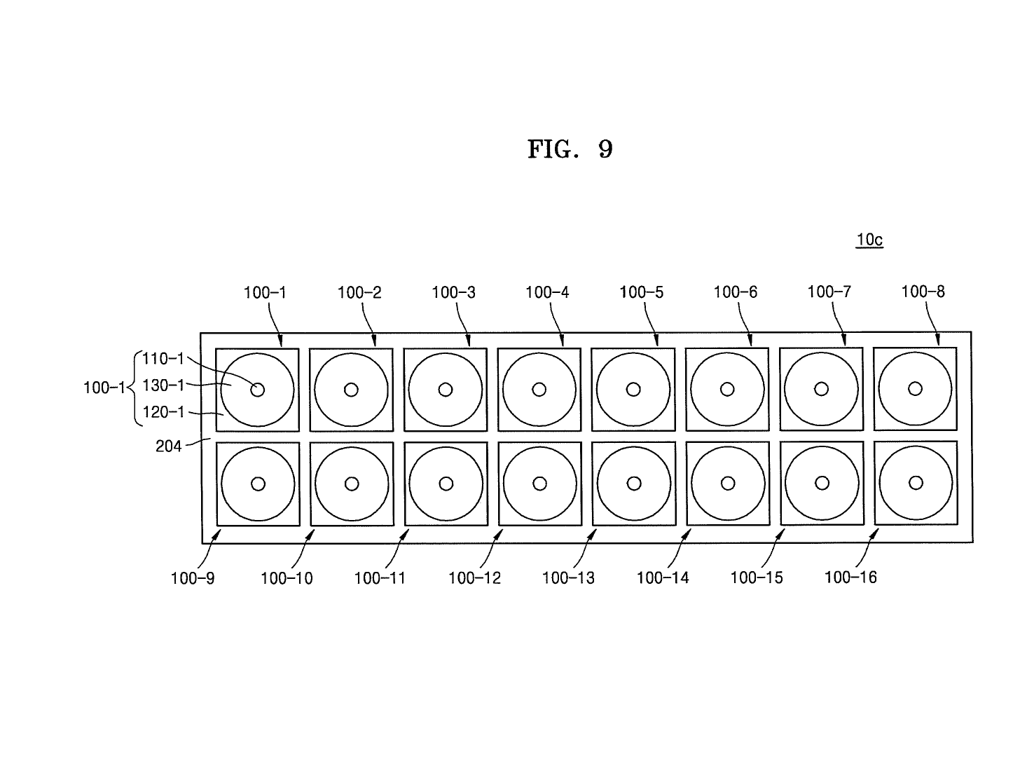

FIG. 9 is a bottom view of a semiconductor package test handler 10c according to an example embodiment of the inventive concept.

Referring to FIG. 9, the semiconductor package test handler 10c may include a plurality of test blades 100-1 to 100-16, and a pusher block 204 connected to the plurality of test blades 100-1 to 100-16.

The plurality of test blades 100-1 to 100-16 may include a first array including first to eighth test blades 100-1 to 100-8 and a second array including ninth to sixteenth test blades 100-9 to 100-16. However, the plurality of test blades 100-1 to 100-16 are not limited two arrays, each of which includes 8 test blades. For example, the plurality of test blades 100-1 to 100-16 may include a plurality of arrays, each of which includes at least one test blade. Each of the plurality of test blades 100-1 to 100-16 may be the same as the test blade 100 shown in FIGS. 3 through 6 and thus, detailed descriptions thereof are omitted.

The semiconductor package test handler 10c may include 2 arrays, each of which may include 8 test blades, and apply pressure to 16 semiconductor packages and simultaneously mount the 16 semiconductor packages on socket structures. The 16 test blades 100-1 to 100-16 may correspond to 16 test sockets 4 that may be arranged in two columns, each of which includes 8 test sockets 4, as shown in FIG. 2.

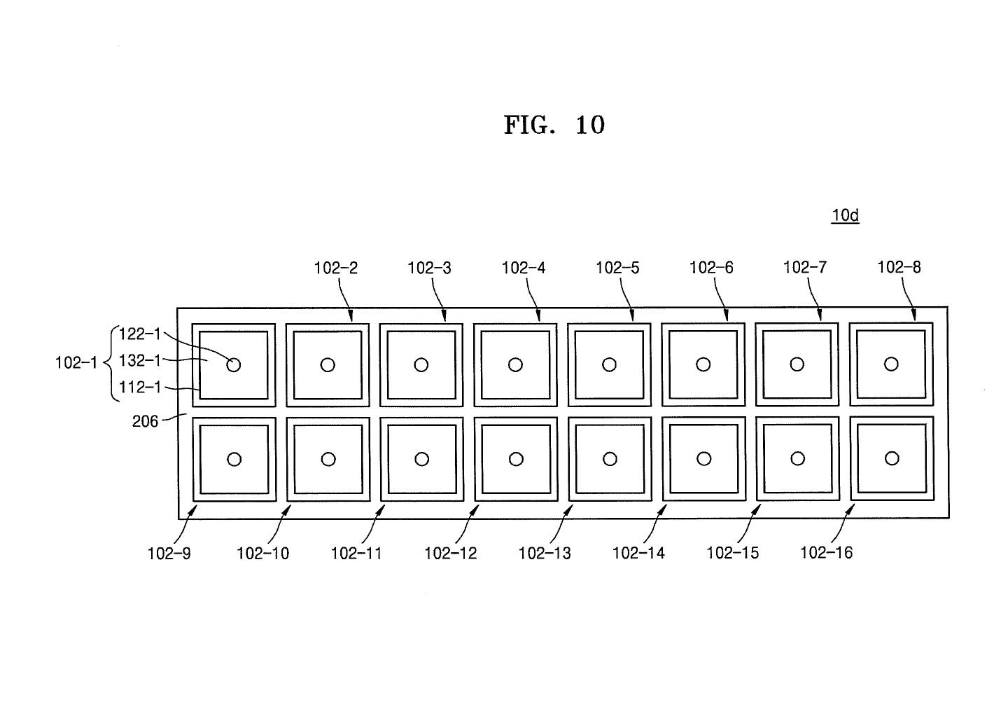

FIG. 10 is a bottom view of a semiconductor package test handler 10d according to an example embodiment of the inventive concepts.

Referring to FIG. 10, the semiconductor package test handler 10d may include a plurality of test blades 102-1 to 102-16 and a pusher block 206 connected to the plurality of test blades 102-1 to 102-16.

The plurality of test blades 102-1 to 102-16 may include a first array including first to eighth test blades 102-1 to 102-8 and a second array including ninth to sixteenth test blades 102-9 to 102-16. Each of the plurality of test blades 102-1 to 102-16 may be the same as the test blade 102 shown in FIG. 7 and thus, repeated descriptions thereof are emitted.

The semiconductor package test handler 10d shown in FIG. 10 differs from the semiconductor package test handler 10e shown in FIG. 9 in terms of shapes of the plurality of test blades 102-1 to 102-16. Accordingly, the shapes of the plurality of test blades 102-1 to 102-16 will be understood with reference to FIG. 7, and the same descriptions of the semiconductor package test handler 10d as in the semiconductor package test handler 10c shown in FIG. 9 will be omitted.

While the inventive concepts have been particularly shown and described with reference to example embodiments thereof, it will be understood that various changes in form and details may be made therein without departing from the spirit and scope of the following claims.

What is claimed is:

1. A semiconductor package test blade comprising:
a blade body at a lower end portion of a pusher for testing a semiconductor package, the blade body having a first surface contacting the semiconductor package and a groove dented upward from the first surface to provide a second surface at a higher level than the first surface and opposite to the first surface;
a vacuum suction picker configured to penetrate a central portion of the blade body and suck and pick up the semiconductor package by using a vacuum; and
a flexible silicone layer filling the groove and being in contact with the second surface of the blade body,
wherein a bottom surface of the flexible silicone layer is at substantially a same level as the first surface of the blade body.

2. The semiconductor package test blade of claim 1, wherein the flexible silicone layer is formed of flexible silicone having a hardness of 1 to 10.

3. The semiconductor package test blade of claim 1, wherein the flexible silicone layer comprises flexible silicone, or flexible silicone rubber.

4. The semiconductor package test blade of claim 1, wherein the flexible silicone layer has a smaller planar area than a planar area of the blade body.

5. The semiconductor package test blade of claim 1, wherein a bottom side of the vacuum suction picker and the bottom surface of the flexible silicone layer are in contact with a top surface of the semiconductor package.

6. The semiconductor package test blade of claim 1, wherein a sum of a planar area the flexible silicone layer and a planar area of the vacuum suction picker is greater than a planar area of a semiconductor chip included in the semiconductor package to cover the semiconductor chip.

7. The semiconductor package test blade of claim 1, wherein the first surface of the blade body is disposed in an outward direction relative to the second surface of the blade body.

8. The semiconductor package test blade of claim 1, wherein a bottom side of the vacuum suction picker has a circular cross-sectional shape, and
wherein a bottom surface of the flexible silicone layer has a concentric cross-sectional shape with the vacuum suction picker.

9. The semiconductor package test blade of claim 1, wherein a bottom side of the vacuum suction picker has a circular cross-sectional shape, and
wherein a bottom surface of the flexible silicone layer has a squared cross-sectional shape to surround the vacuum suction picker.

10. A semiconductor package test apparatus comprising:
a plurality of test blades disposed in a row apart from one another, each test blade including a vacuum suction picker configured to suck and pick up a semiconductor package;
a pusher block connected to the plurality of test blades and including a vacuum path communicate with each vacuum suction picker; and
flexible silicone layers each formed on a first surface of each of the plurality of test blades, which are in contact with the semiconductor package.

11. The semiconductor package test apparatus of claim 10, further comprising protrusions at outer portions of the first surfaces of the plurality of test blades.

12. The semiconductor package test apparatus of claim 11, wherein bottom surfaces of the protrusions are at substantially a same level as a bottom surface of the flexible silicone layers.

13. The semiconductor package test apparatus of claim 10, wherein the pusher block is connected to a test handler, and is in contact with second surfaces of the plurality of test blades opposite to the first surfaces thereof.

14. The semiconductor package test apparatus of claim 10, wherein the test blades include at least one array including 8 test blades arranged in a row.

15. The semiconductor package test apparatus of claim 10, wherein the flexible silicone layer comprises flexible silicone having a hardness of 1 to 10.

16. A semiconductor package test blade comprising:
a vacuum suction unit configured to suck and pick up a semiconductor package;
a body unit configured to surround the vacuum suction unit, wherein a groove is formed to a predetermined depth in a surface of the body unit, which is in contact with the semiconductor package; and
a flexible silicone layer configured to fill the groove.

17. The semiconductor package test blade of claim 16, wherein the flexible silicone layer comprises flexible silicone having a hardness of 1 to 10.

18. The semiconductor package test blade of claim 16, wherein the vacuum suction unit is proximal to the center of the body unit,
the flexible silicone layer is symmetrically positioned with respect to the vacuum suction unit.

19. The semiconductor package test blade of claim 16, wherein the vacuum suction unit is positioned in the center of the body unit, and the flexible silicone layer is configured as a donut type around the vacuum suction unit.

20. The semiconductor package test blade of claim 16, wherein a lowermost surface of the body unit is at substantially a same level as a lowermost surface of the flexible silicone.
